(19) United States
(12) Patent Application Publication
(10) Pub. No.: US 2021/0284812 A1
(43) Pub. Date: Sep. 16, 2021

(54) METHOD FOR PRODUCING AN ELECTRONIC DEVICE

(71) Applicant: Merck Patent GmbH, Darmstadt (DE)

(72) Inventors: Holger HEIL, Frankfurt am Main (DE); Matthias KOCH, Wiesbaden (DE); Nathan SMITH, Southampton (GB)

(73) Assignee: Merck Patent GmbH, Darmstadt (DE)

(21) Appl. No.: 17/255,571

(22) PCT Filed: Jun. 25, 2019
(86) PCT No.: PCT/EP2019/066740

§ 371 Date: Dec. 23, 2020

(30) Foreign Application Priority Data
Jun. 28, 2018 (EP) 18180606.8

(51) Int. Cl. C08J 5/18; H01L 51/52; C08G 61/08; H01L 51/00; C09D 11/101; C09D 11/106; C09D 11/30

(52) U.S. Cl. CPC C08J 5/18; C08G 2150/00; H01L 51/5221; H01L 51/5253; C08G 61/08; H01L 51/0005; C09D 11/101; C09D 11/106; C09D 11/30; C08G 2261/148; C08G 2261/3324; C08G 2261/95; C08J 2365/00; C08G 2261/146; C08G 2261/149; C08G 2261/144; H01L 51/5206

(57) ABSTRACT

The present application relates to a method for producing a polycycloolefin layer, to electronic devices produced by such method and comprising such layer as well as to formulations used for making such polycycloolefin layer.

### TECHNICAL FIELD

The present application relates to a method for producing a polycycloolefin layer, to electronic devices produced by such method and comprising such layer as well as to formulations used for making such polycycloolefin layer.

### BACKGROUND

Electronic devices, and particularly organic electronic devices, are sensitive to environmental influences, especially to oxygen and water. If not protected, their performance will degenerate over time, in some instances even rather quickly. Such degradation would hamper commercial uses because users generally expect these devices to have a lifetime of at least a few years.

Thus, along with the development of organic electronic devices, such as organic light emitting diodes, organic thin film transistors or organic photovoltaic cells, to only name a few, concepts for their protection from harmful influences, such as water and/or oxygen have been developed. To provide sufficient protection against such harmful influences the current concepts generally require a combination of inorganic layers and organic layers. Such an approach, however, has the disadvantage that such layers, particularly the organic layers, need to be sufficiently thick so as to eliminate or at least reduce the formation of pinholes in the layer, which would allow oxygen and/or water to directly get into the electronic device and induce a rapid degradation of the functional layers and consequently of device performance.

Thus, there is a need to further improve the existing concepts for protecting electronic devices, i.e. to further improve the so-called encapsulation layer(s).

It is therefore an object of the present application to provide for an encapsulation which improves on the disadvantages of the known concepts as well as provide improved properties, selected from one or more of optical properties, electronic properties and mechanical properties.

### SUMMARY OF THE INVENTION

The present inventors have now surprisingly found that the above objects may be attained either individually or in any combination by the present method as well as by the present polymer, formulation and electronic device.

The present application therefore provides for a method for producing a film, said method comprising the steps of
(a) providing an base member;
(b) depositing the formulation as defined in any one or more of claims 25 to 37 on the base member; and
(c) polymerizing the monomers comprised in said formulation to obtain a polycycloolefin layer

The present application therefore also provides for an electronic device comprising
(a) a base member; and
(b) a polycycloolefin film (layer) comprising the polycycloolefin of the present application.

Furthermore, the present application provides for a polycycloolefin comprising at most 20 wt % of atoms different from H, F and C, with wt % being relative to the total weight of the polycycloolefin.

Additionally, the present application provides for a formulation comprising a transition metal compound and one or more cycloolefin monomers, wherein said cycloolefin monomers comprise at most 5 wt % of atoms different from H, F and C, with wt % relative to the total weight of the cycloolefin monomers.

### BRIEF DESCRIPTION OF THE DRAWINGS

FIG. 1 is an exemplary schematic representation of a display device (100) comprising in sequence a substrate (101), a circuit layer (102), a display layer (103), a planarization layer (104), an optional thin film encapsulation layer (105) and a touch sensor layer (106).

### DETAILED DESCRIPTION OF THE INVENTION

In general, unless indicated otherwise, respective weight percentages are to add up to 100 wt %.

For the purposes of the present application the term “organic electronic device” is used to denote an electronic device comprising a functional layer, which comprises more that 50 wt % of one or more organic material, with wt % relative to the total weight of said functional layer. Examples of such functional layers include, but are not limited to, light emitting layer, semiconductor layer, or photoactive layers.

For the purposes of the present application the term “inorganic electronic device” is used for all electronic devices other than organic electronic devices as defined above.

The term “hybrid electronic device” is used to denote an electronic device comprising a functional layer comprising more than 50 wt % of an organic material and a functional layer comprising more than 50 wt % of an inorganic material, with wt % relative to the total weight of the respective functional layer.

Method

In general terms, the present application relates to a method of producing a polycycloolefin film (or “layer” as it may be referred to when comprised in a device, for example, an electronic device). This method of producing such a film comprises the steps of
(a) providing a base member,
(b) depositing a formulation on the base member, and
(c) polymerizing the monomers comprised in the formulation to obtain a polycycloolefin layer.

Additionally, the present method may comprise the further step of
(d) depositing one or more additional layers onto the polycycloolefin layer.

Such one or more additional layer is preferably selected from the group consisting of organic layers, inorganic layers and hybrid layers as defined in more detail herein.

The present method may, for example, be used in the production of an electronic device as described in more detail in the following.

Polycycloolefin

The polycycloolefin used herein comprises at most 20 wt %, preferably at most 18 wt % or 16 wt %, more preferably at most 14 wt % or 12 wt %, even more preferably at most 10 wt % or 9.0 wt % or 8.0 wt % or 7.0 wt %, still even more preferably at most 6.0 wt %, and most preferably at most 5.0 wt % of atoms different from H, F and C (i.e. of “heteroatoms”), with wt % relative to the total weight of the polycycloolefin. Alternatively the polycycloolefin used herein may also comprise less than 5.0 wt %, for example at most 4.0 wt % or 3.0 wt % or 2.0 wt % or 1.0 wt % or 0.05 wt % or 0.01 wt %, with wt % relative to the total weight of the polycycloolefin, of atoms different from H, F and C.

The polycycloolefin used herein preferably has a weight average molecular weight (Mw) of at least 100,000 g mol⁻¹, more preferably of at least 200,000 g mol⁻¹ or 300,000 g mol⁻¹, even more preferably of at least 400,000 g mol⁻¹, and most preferably of at least 500,000 g mol⁻¹, determined by GPC as described below.

Molecular weights of the polynorbornenes may be determined by gel permeation chromatography (GPC) on commercially available equipment, having two Phenomenex Phenogel Linear Column and a Phenogel 10⁶ Å Column (all columns are 10 μm packed capillary columns) and a refractive index detector, in chlorobenzene at 50° C. using commercially available narrow molecular weight standards of polystyrene for calibration.

The polycycloolefin used herein is preferably characterized by a permittivity E of at most 4.0, preferably of at most 3.5, more preferably of at most 3.0, even more preferably of at most 2.8, still even more preferably of at most 2.6. The polycycloolefin used herein preferably has a permittivity of at least 0.1, more preferably of at least 0.5, even more preferably of at least 1.0, for example, of at least 1.1 or 1.2 or 1.3 or 1.4 or 1.5 or 1.6 or 1.7 or 1.8 or 1.9 or 2.0. Throughout this application, the values for the permittivity or dielectric constant E refer to values taken at 20° C. and 1,000 Hz.

The polycycloolefin used herein preferably comprises at least 50 wt % or 60 wt % or 70 wt %, more preferably at least 80 wt % or 90 wt %, even more preferably at least 95 wt % or 97 wt % or 99.0 wt %, still even more preferably at least 99.5 wt % or 99.7 wt % or 99.9 wt %, and most preferably consists of cycloolefin constitutional units, with wt % being relative to the total weight of the polycycloolefin.

Such polycycloolefin may, for example, by represented by the following formula (I)

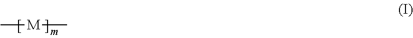

wherein M is at each occurrence independently a constitutional unit as defined herein, and m is an integer >10 selected in such a way that the resulting polycycloolefin has the above-defined weight average molecular weight (Mw).

Suitable examples of polycycloolefinic polymers are preferably selected from polynorbornenes. For the purposes of the present application the term “polynorbornene” is used to denote a polymer comprising norbornadiyl monomeric units of generalized and simplified formula (A′) or derivatives thereof obtained by addition polymerization of norbornene monomer of generalized and simplified formula (A) or derivatives thereof.

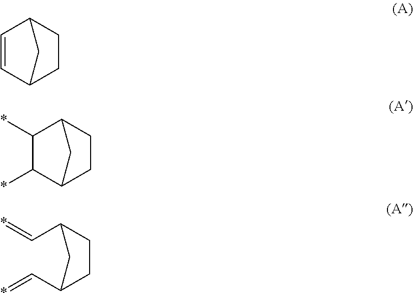

More specifically, suitable examples of polycycloolefinic polymers may be obtained by addition polymerization of monomers of the following formula (II) or of a mixture of monomers comprising monomers of the following formula (I), and thus comprise constitutional units M of the following formula (II′)

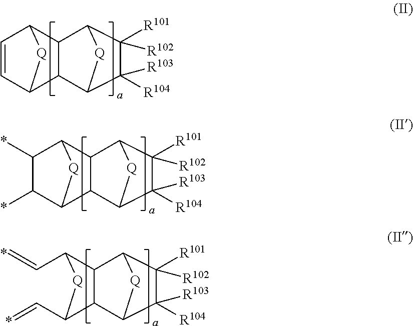

with a, Q, R¹⁰¹, R¹⁰², R¹⁰³, and R¹⁰⁴ as defined herein.
a is at each occurrence independently an integer of from 0 to 5, e.g. 0, 1, 2, 3, 4 or 5. Preferably a is an integer from 0 to 3, e.g. 0, 1, 2 or 3. More preferably a is 0 or 1. Most preferably a is 0.

Q is at each occurrence independently selected from the group consisting of —CH₂—, —CH₂—CH₂—, —CF₂—, —CF₂—CF₂— and O. Preferably Q is selected from the group consisting of —CH₂—, —CH₂—CH₂— and O. Most preferably Q is —CH₂—.

Though all of substituents R¹⁰¹, R¹⁰², R¹⁰³, and R¹⁰⁴ may be different from hydrogen, it is nevertheless preferred that only one of R¹⁰¹, R¹⁰², R¹⁰³, and R¹⁰⁴ is different from hydrogen and as defined in the following, while the other three of R¹⁰¹, R¹⁰², R¹⁰³, and R¹⁰⁴ are hydrogen.

R¹⁰¹, R¹⁰², R¹⁰³, and R¹⁰⁴ are at each occurrence independently of each other selected from the group consisting of hydrogen, fluorine, hydrocarbyl groups, partially fluorinated hydrocarbyl groups and fully fluorinated hydrocarbyl groups.

As used herein, the term “hydrocarbyl” is used to denote univalent groups formed by removing a hydrogen atom from a hydrocarbon, i.e. a compound consisting solely of hydrogen and carbon atoms. The term “partially fluorinated hydrocarbyl group” is used to denote a hydrocarbyl group wherein at least one but not all hydrogen atoms are replaced by fluorine. The term “fully fluorinated hydrocarbyl group” is used to denote a hydrocarbyl group wherein all hydrogen atoms are replaced by fluorine.

Hydrocarbyl groups particularly suitable as R¹⁰¹, R¹⁰², R¹⁰³, and R¹⁰⁴ may be selected from the group consisting of alkyl groups (including cycloalkyl groups), aryl groups, aralkyl groups (i.e. an alkyl group wherein one or more hydrogen atom is replaced by an aryl group), and alkylaryl groups (i.e. aryl wherein one or more hydrogen atom is replaced by an alkyl group). For reasons of clarity it is noted that all of these—including any respective substituents—may also be fully or partially fluorinated.

Exemplary alkyl groups have at least 1 carbon atom and at most 30, preferably at most 25, more preferably at most 20, even more preferably at most 15, and most preferably at most 10 carbon atoms. Such alkyl groups may generally be represented as —(CH₂)_{b}—CH₃ with b being an integer of at least 1 and of at most 14 (for example 2, 3, 4, 5, 6, 7, 8, 9, 10, 11, 12 or 13). Such alkyl groups may be linear, branched, or cyclic; it is also possible to have a cycloalkyl group substituted with a linear or branched alkyl group, which may then be bonded to the norbornene unit via the linear or branched alkyl group or via the cycloalkyl group.

Examples of suitable linear and branched alkyl groups may, for example, be selected from the group consisting of methyl, ethyl, propyl, isopropyl, butyl, isobutyl, sec-butyl, tert-butyl, pentyl, neopentyl, hexyl, heptyl, octyl, nonyl, decyl and dodecyl.

Exemplary perfluorinated, alkyl groups may, for example, be selected from the group consisting of trifluoromethyl, —C₂F₅, —C₃F₇, —C₄F₉, —C₆F₁₃—, —C₇F₁₅, and —C₁₁F₂₃.

Examples of suitable cycloalkyl groups may, for example, be selected from the group consisting of cyclopentyl, cyclohexyl, and cyclooctyl, which may optionally be substituted with one or more linear or branched alkyl group as defined above, provided that the total number of carbon atoms does not exceed what has been defined above in respect to alkyl groups.

Exemplary aryl groups have at least 6 and at most 24 aromatic carbon atoms, and may optionally be substituted with one or more alkyl group having from 1 to 10 carbon atoms. Examples of suitable aryl groups may be selected from the group consisting of phenyl, biphenyl, naphthyl, and anthracenyl.

Exemplary aralkyl groups may be selected from alkyl groups —(CH₂)_{b}—CH₃ as defined above, wherein one or more hydrogen atoms has been replaced by an aryl group as defined above.

Suitable aralkyl groups may, for example, be represented as —(CH₂)_{b}—Ar with b as defined above, and Ar as defined above for aryl groups. The alkanediyl group —(CH₂)_{b}— with b as defined above may be linear, branched, or cyclic.

Examples of suitable aralkyl groups may be selected from the group consisting of benzyl (Ph-CH₂—), phenethyl (Ph-(CH₂)₂—) and phenbutyl (Ph-(CH₂)₄—).

Examples of suitable partially or fully fluorinated aryl and aralkyl groups may be selected from the group consisting of formulae —(CH₂)ₓ—C₆F_{y}H_{5-y} where x is an integer from 0 to 5 and y is an integer from 1 to 5, and —(CH₂)ₓ—C₆F_{y}H_{4-y}-pC_{z}F_{q}H_{2z+1-q} where x is an integer from 0 to 5, y is an integer from 1 to 4, z is an integer from 1 to 4, and q is an integer from 1 to 2z+1. Specifically, such exemplary fluorinated or perfluorinated, aryl groups include, but are not limited to, pentafluorophenyl, pentafluorobenzyl, 4-trifluoromethylbenzyl, pentafluoro-phenethyl, pentafluorophenpropyl, and pentafluorophenbutyl.

Exemplary alkylaryl groups may be selected from aryl groups as defined above, wherein one or more hydrogen atom is replaced by an alkyl group of formula —(CH₂)_{b}—CH₃ as defined above.

It is noted that two or more of groups R¹⁰¹, R¹⁰², R¹⁰³ and R¹⁰⁴ together may form a ring, such as a saturated ring (e.g. a cycloalkane) or a non-saturated ring.

Preferred norbornene monomers may at each occurrence independently be selected from the group consisting of the following formula (II-a-01) to (II-a-19)

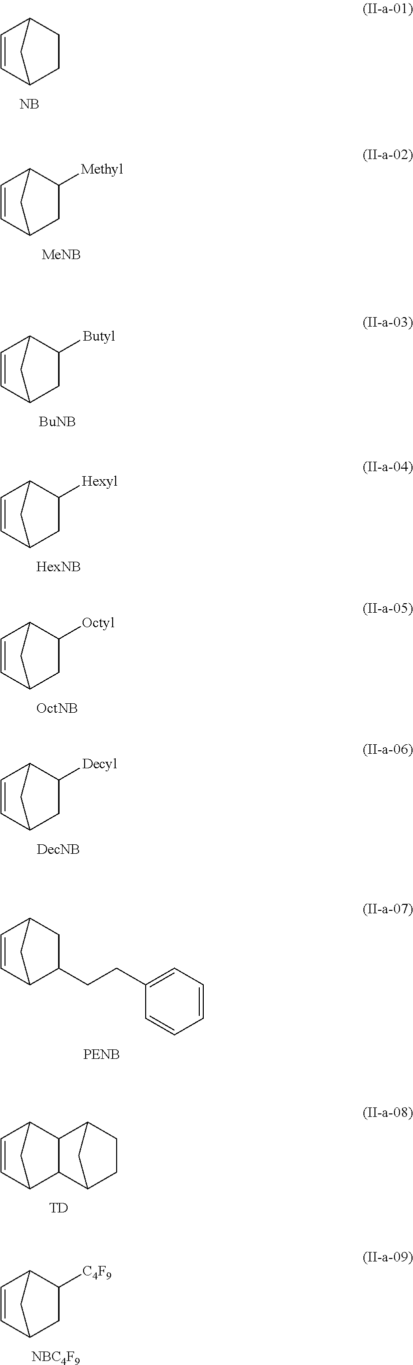

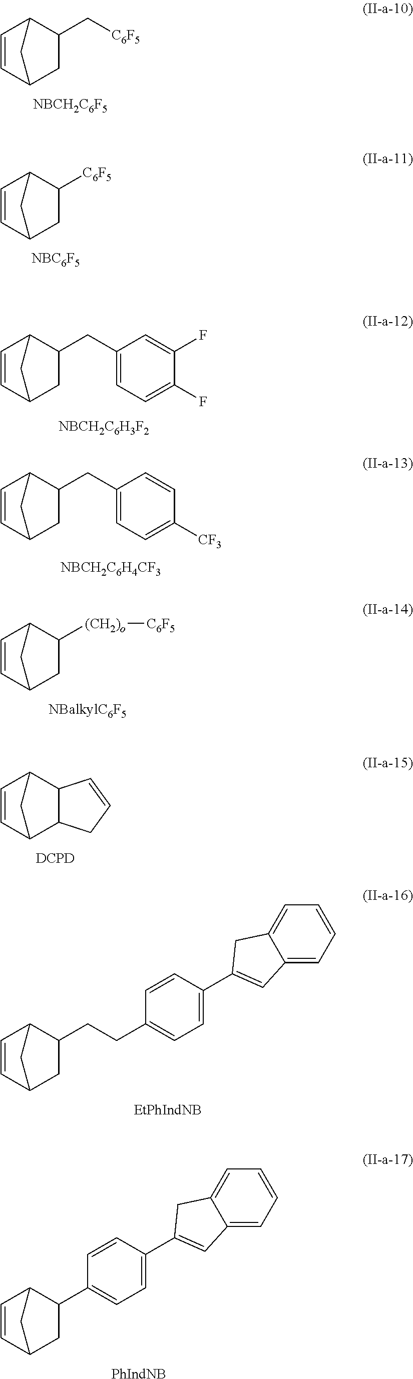

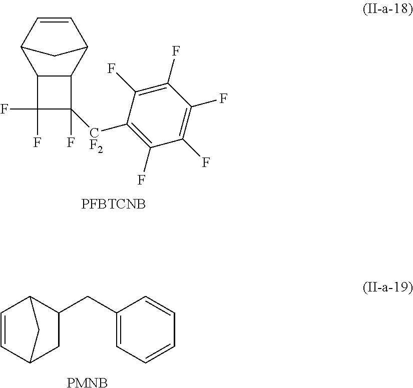

wherein “Me” stands for methyl, “Et” for ethyl, “Ph” and “C₆H₅” for phenyl, “C₆F₅” for pentafluorophenyl, o is an integer from 1 to 8; and for each of the above subformulae having a methylene bridging group (a CH₂ covalently bonded to both the norbornene ring and a functional group), including but not limited to (II-a-10), (II-a-12), (II-a-13) and (II-a-19), it will be understood that the methylene bridging group can be replaced by a covalent bond or —(CH₂)ₒ— as in formula (II-a-14), with o then being an integer from 1 to 6.

Provided that the resulting polycycloolefin complies with above requirements regarding the content of H, F and C, the polycycloolefin may also contain cycloolefin constitutional units, preferably norbornene constitutional units, comprising atoms other than H, F and C, in the following referred to as “heteroatom(s)”.

For the purposes of the present application the terms “heteroatom-hydrocarbyl” and “heterohydrocarbyl” are used to denote any hydrocarbyl comprising one or more heteroatom, i.e. comprising one or more atom other than H, F and C.

Examples of such heterohydrocarbyl groups may be selected from the group consisting of hydrocarbyl groups, wherein one or more non-adjacent carbon atom is replaced by the respective number of heteroatom groups selected from the group consisting of O, S, NR, PR and SiR₂, preferably from the group consisting of O, NR, PR and SiR₂, and most preferably O or SiR₂, wherein R may at each occurrence independently be selected from the group consisting of hydrogen, C₁-C₁₁ alkyl, C₅-C₁₂ cycloalkyl, C₆-C₁₄ aryl, and C₇-C₁₄ aralkyl, all of which may also be fully or partially fluorinated.

Such heterohydrocarbyl groups, optionally partially or fully fluorinated, suitable as R¹⁰¹, R¹⁰², R¹⁰³ and R¹⁰⁴ may be selected from the group consisting of the following formulae

| | |
|---|---|
| —(CH₂)_{c}—Ar—(CH₂)_{c}—C(CF₃)₂—OH, | —(CH₂)_{c}—Ar—(CH₂)_{c}—OCH₂C(CF₃)₂—OH, |
| —(CH₂)_{c}—C(CF₃)₂—OH, | —((CH₂)_{d}—O—)ₑ—(CH₂)—C(CF₃)₂—OH, |
| —(CH₂)_{c}—C(CF₃)(CH₃)—OH, | —(CH₂)_{c}—C(O)NHR*, |
| —(CH₂)_{c}—C(O)Cl, | —(CH₂)_{c}—C(O)OR*, |
| —(CH₂)_{c}—OR*, | —(CH₂)_{c}—OC(O)R*, and |
| —(CH₂)_{c}—C(O)R*, | |

wherein
c at each occurrence independently represents an integer from 0 to 12 (for example 1, 2, 3, 4, 5, 6, 7, 8, 9, 10, 11, or 12);
d is 2, 3 or 4;
e is 1, 2 or 3;
Ar is aryl having at least 6 and at most 24 aromatic carbon atoms, optionally substituted with one or more alkyl group having from 1 to 10 carbon atoms, with exemplary suitable aryl groups being selected from the group consisting of phenyl, biphenyl, naphthyl, and anthracenyl, preferably being phenyl, all of which may also be fully or partially fluorinated (including the alkyl substituent—if present); and
R* may at each occurrence independently be selected from the group consisting of hydrogen, C₁-C₁₁ alkyl, C₅-C₁₂ cycloalkyl, C₆-C₁₄ aryl, and C₇-C₁₄ aralkyl, all of which may also be fully or partially fluorinated.

Suitable heterohydrocarbyl groups may, for example, also be represented by the following formula (III)

—[X¹⁰¹_{f}—R¹⁰⁵_{g}—X¹⁰²ₕ]ᵢ—R¹⁰⁶ (III)

with i, f, g, h, R¹⁰⁵, R¹⁰⁶, X¹⁰¹ and X¹⁰² as defined herein; and
i is at each occurrence independently an integer of from 0 to 5. Thus, i may at each occurrence independently be selected from the group consisting of 0, 1, 2, 3, 4, and 5. Preferably, i may at each occurrence independently be selected from the group consisting of 0, 1, 2, and 3. More preferably, i may at each occurrence independently be selected from the group consisting of 0, 1, and 2. Even more preferably, i is at each occurrence independently 1 or 2. Most preferably, i is 1.
f, g and h are at each occurrence independently 0 or 1. If f, g or h is 1 then the respective group R¹⁰⁵, X¹⁰¹ and X¹⁰² is present and if f, g or h is 0 then the respective group is absent.

Thus, exemplary groups of formula (III) may at each occurrence independently be selected from the following group consisting of formulae (III-1) to (III-10)

—R¹⁰⁶ (III-1)

—R¹⁰⁵—R¹⁰⁶ (III-2)

—X¹⁰¹—R¹⁰⁶ (III-3)

—X¹⁰¹—R¹⁰⁵—R¹⁰⁶ (III-4)

—R¹⁰⁵—X¹⁰²—R¹⁰⁶ (III-5)

—X¹⁰¹—R¹⁰⁵—X¹⁰²—R¹⁰⁶ (III-6)

—R¹⁰⁵—X¹⁰²—R¹⁰⁵—R¹⁰⁶ (III-7)

—X¹⁰¹—R¹⁰⁵—X¹⁰²—R¹⁰⁵—R¹⁰⁶ (III-8)

—R¹⁰⁵—X¹⁰²—R¹⁰⁵—X¹⁰²—R¹⁰⁶ (III-9)

—R¹⁰⁵—X¹⁰²—R¹⁰⁵—X¹⁰²—R¹⁰⁵—R¹⁰⁶ (III-10)

with R¹⁰⁵, R¹⁰⁶, X¹⁰¹ and X¹⁰² as defined herein.

X¹⁰¹ and X¹⁰² are at each occurrence independently selected from the group consisting of —O—, —C(═O)—, —C(═O)—O—, —S—, —NR¹⁰⁸—, —PR¹⁰⁸— and —Si(R¹⁰⁸)₂—, and are preferably selected from the group consisting of —O—, —C(═O)—, and —C(═O)—O—, wherein R¹⁰⁸ is as defined herein.

R¹⁰⁵ is at each occurrence independently selected from the group consisting of
(i) alkanediyl having from 1 to 20, preferably from 1 to 15, more preferably from 1 to 10 carbon atoms;
(ii) partially or fully halogenated, preferably fluorinated, alkanediyl having from 1 to 20, preferably from 1 to 15, more preferably from 1 to 10 carbon atoms;
(iii) 1,4-phenylene and 1,4-phenylene wherein one or more hydrogen atoms are substituted by a group R¹⁰⁸ as defined herein.

R¹⁰⁶ is at each occurrence independently selected from the group consisting of
(i) methyl;
(ii) partially or fully halogenated, preferably fluorinated, methyl;
(iii) —Si(R¹⁰⁷)₃ or —Si(OR¹⁰⁷)₃, wherein R¹⁰⁷ is at each occurrence independently selected from alkyl having from 1 to 10, preferably from 1 to 5 carbon atoms; partially or fully halogenated, preferably fluorinated, alkyl having from 1 to 10, preferably from 1 to 5 carbon atoms; phenyl; phenyl wherein one or more hydrogen atoms is replaced by a group R¹⁰⁸ as defined herein;
(iv) aryl having from 6 to 20 aromatic ring atoms and aryl having from 6 to 20 aromatic ring atoms wherein one or more hydrogen is replaced by a group R¹⁰⁸ as defined herein.

R¹⁰⁸ may at each occurrence independently be selected from the group consisting of halogen, preferably fluorine; alkyl having from 1 to 10, preferably from 1 to 5 carbon atoms, more preferably methyl; partially or fully halogenated, preferably fluorinated, alkyl having from 1 to 10, preferably from 1 to 5 carbon atoms, more preferably methyl; alkoxy having from 1 to 10, preferably from 1 to 5 carbon atoms, more preferably methoxy; and partially or fully halogenated, preferably fluorinated, alkoxy having from 1 to 10, preferably from 1 to 5 carbon atoms, more preferably methoxy.

Preferred heteroatom-comprising norbornene monomers may at each occurrence independently be selected from the group consisting of formula (II-b-01) to (II-b-15)

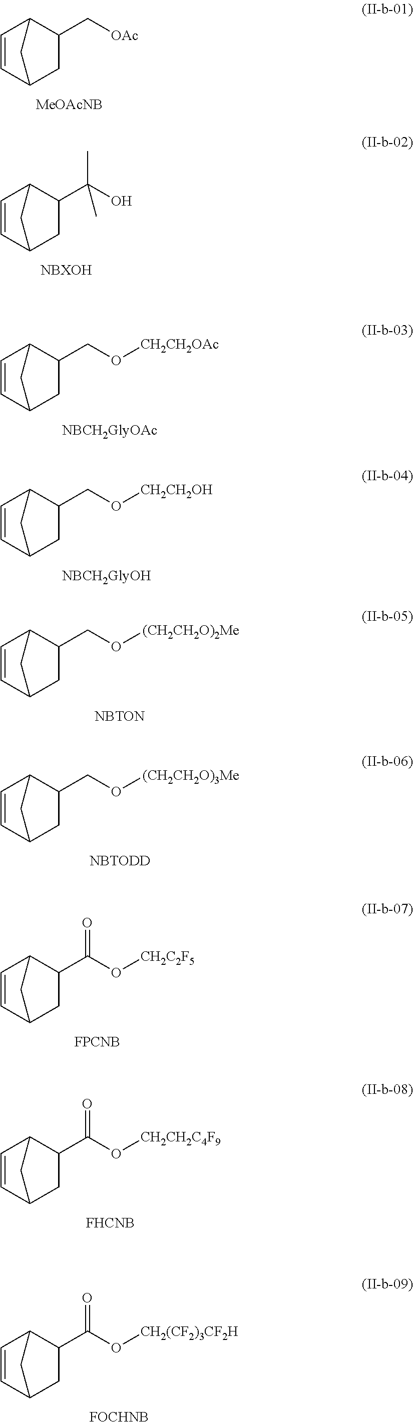

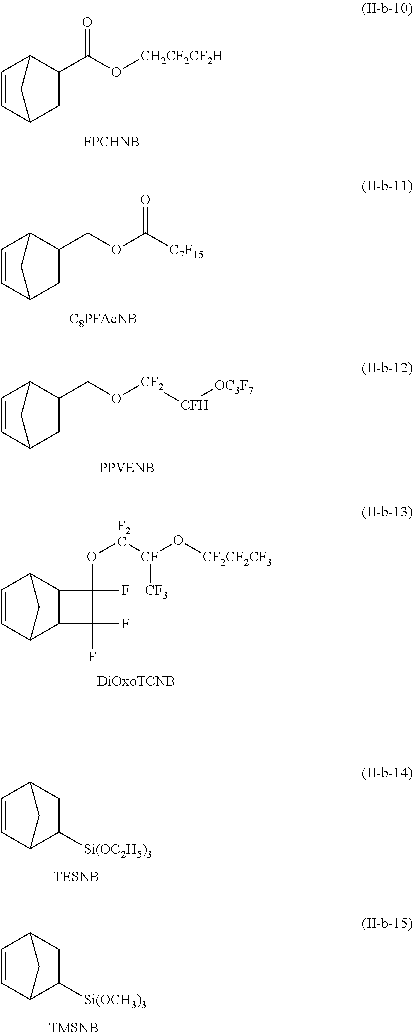

wherein “Me” stands for methyl, “OAc” for acetate, and for each of the above subformulae having a methylene bridging group (a CH₂ covalently bonded to both the norbornene ring and a functional group), including but not limited to (II-b-01) and (II-a-12), it will be understood that the methylene bridging group can be replaced by a covalent bond or —(CH₂)ₒ— as in formula (II-a-14), with o then being an integer from 1 to 6.

Optionally, the present polycycloolefin may further comprise at most 20 wt % (for example 18 wt %, 16 wt %, 14 wt % or 12 wt %), preferably at most 10 wt % (for example 9.0 wt %, 8.0 wt %, 7.0 wt %, 6.0 wt %, 5.0 wt %, 4.0 wt %, 3.0 wt % or 2.0 wt %), more preferably at most 1.0 wt % or 0.5 wt %, even more preferably at most 0.4 wt % or 0.3 w % or 0.2 wt % or 0.1 wt %, still even more preferably at most 0.05 wt % or 0.03 wt % or 0.01 wt %, and most preferably none, of cycloolefin constitutional units comprising a reactive group, with wt % relative to the total weight of the polycycloolefin.

Examples of suitable reactive groups may be selected from the group consisting of alkylidene groups (—(R¹⁰⁸)C═C(R¹⁰⁸)—), alkynyl groups (—C≡C—), maleimide; maleimide substituted with one or more groups R¹⁰⁸, preferably alkyl having from 1 to 10, more preferably from 1 to 5 carbon atoms, and most preferably with methyl or ethyl; maleimide having one or more (for example, 1, 2 or 3) annealed aromatic, preferably 6-membered, rings such that the 3- and 4-positions of the maleimide form part of one of the aromatic rings; epoxide, vinyl, acetylene, indenyl, cinnamate, coumarin, dicyclopentadiene and derivatives thereof, for example those wherein one or more hydrogen atoms are replaced by R¹⁰⁸; and more preferably a group selected from 3-monoalkylmaleimide, 3,4-dialkylmaleimide, epoxy, vinyl, acetylene, cinnamate, indenyl, coumarin, dicyclopentadiene and derivatives thereof, for example those wherein one or more hydrogen atoms are replaced by R¹⁰⁸, with R¹⁰⁸ as defined herein.

Preferred norbornene monomers comprising a reactive group may at each occurrence independently be selected from the group consisting of formulae (II-c-01) to (II-c-27), with (II-c-27) being particularly preferred

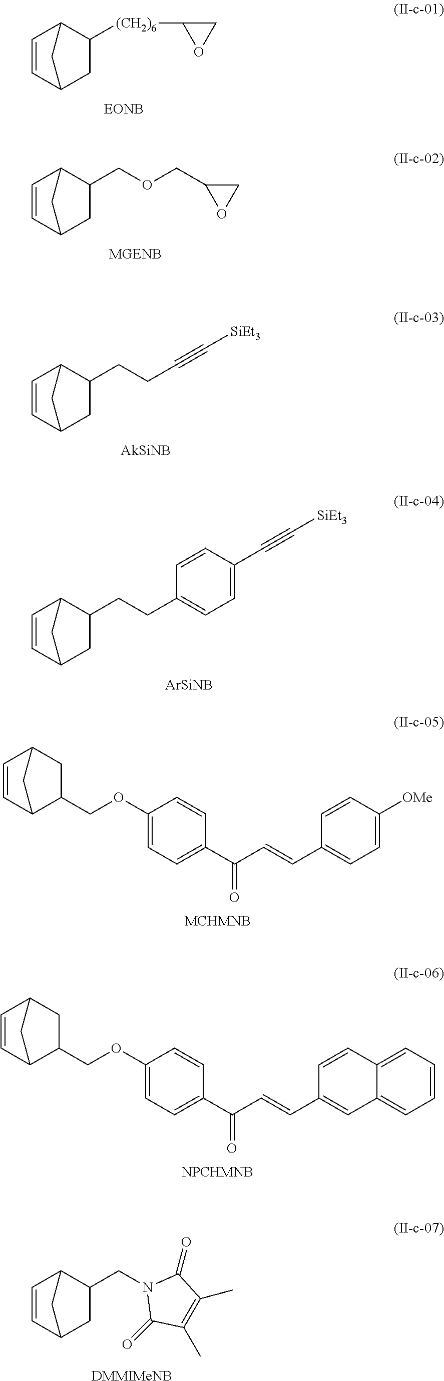

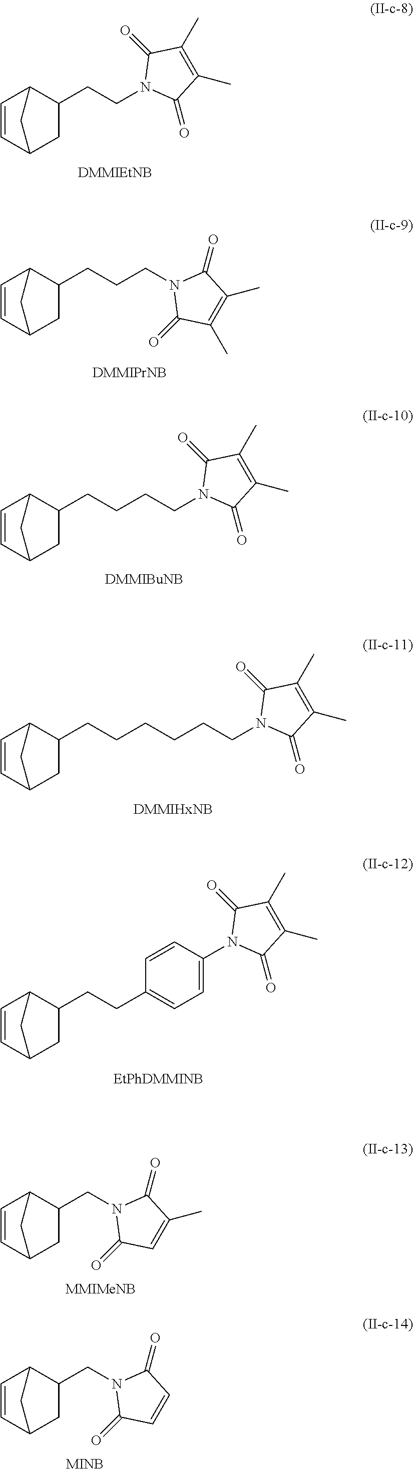

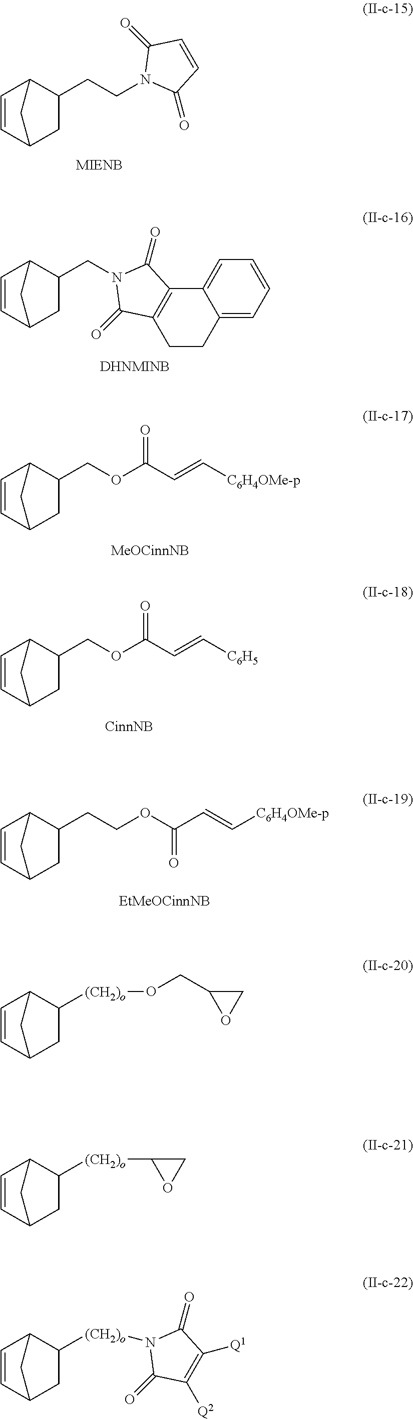

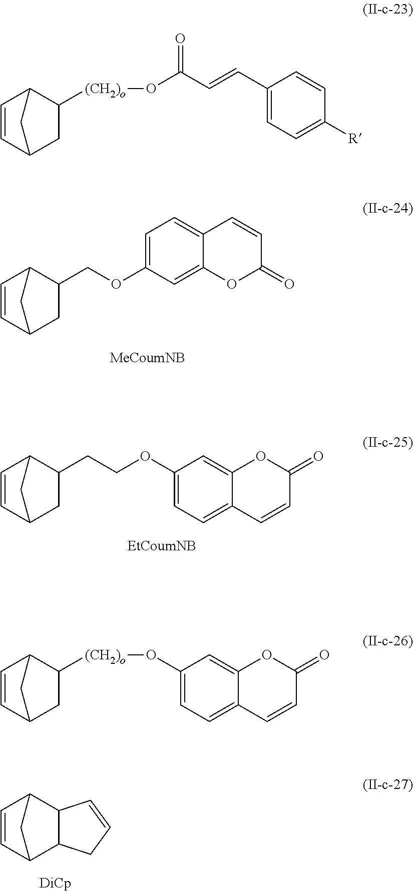

wherein “Me” stands for methyl, “Et” for ethyl, “OMe-p” for para-methoxy, “Ph” and “C₆H₅” for phenyl, “C₆H₄” for phenylene, “C₆F₅” for pentafluorophenyl, “OAc” for acetate, “PFAc” for —OC(O)—C₇F₁₅, o is an integer from 1 to 8, Q1 and Q2 are at each occurrence independently H or —CH₃; R′ is H or —OCH₃; and for each of the above subformulae having a methylene bridging group (a CH₂ covalently bonded to both the norbornene ring and a functional group), including but not limited to (II-c-02), (II-c-05), (II-c-06), (II-c-07), (II-c-13), (II-c-14), (II-c-16), (II-c-17), (II-c-18), and (II-c-24), it will be understood that the methylene bridging group can be replaced by a covalent bond or —(CH₂)— as, for example, in formula (II-c-20), with o then being an integer from 1 to 6.

In a preferred embodiment of the present invention, the norbornene-type polymer incorporates two or more distinct types of repeating units, i.e. the norbornene-type polymer is a copolymer, such as for example a random copolymer or a block copolymer.

In another preferred embodiment of the present invention, the norbornene-type polymer incorporates one or more distinct types of repeating units, where at least one such type of repeating unit encompasses pendant crosslinkable groups or moieties that have some degree of latency. By “latency”, it is meant that such groups do not crosslink at ambient conditions or during the initial forming of the polymers, but rather crosslink when such reactions are specifically initiated, for example by actinic radiation or heat. Such latent crosslinkable groups are incorporated into the polymer backbone by, for example, providing one or more norbornene-type monomers encompassing such a pendant crosslinkable or reactive group as defined herein.

Another preferred embodiment of the present invention is directed to a polymer having a first and a second distinct type of repeat units in accordance with formula (II′) where the ratio of such first and second type of repeat units is from 95:5 to 5:95. In another preferred embodiment the ratio of such first and second type of repeat units is from 80:20 to 20:80. In still another preferred embodiment the ratio of such first and second type of repeat units is from 60:40 to 40:60. In yet another preferred embodiment the ratio of such first and second type of repeat units is from 55:45 to 45:55.

In addition to any cycloolefin constitutional units the present polycycloolefin may also comprise olefin constitutional units derived from olefin monomers, such olefins having from two to ten carbon atoms. Examples of such olefin monomers may be selected from the group consisting of ethylene, propylene, butene-1, butene-2, buta-1,3-diene, pentene-1, pentene-2, hexene-1, hexene-2 and octene-1, with ethylene, propylene, butene-1 and hexene-1 being preferred.

Such olefin constitutional units may, for example, be introduced into the polymer in form of a substituent on the C═C double bond of the norbornene as is illustrated by the following representative formulae

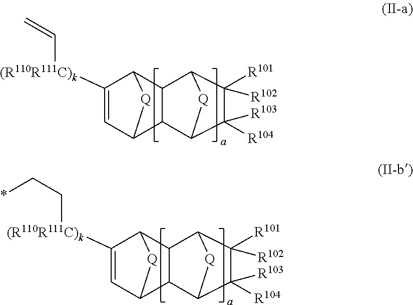

with a, k, Q, R¹⁰¹, R¹⁰², R¹⁰³, R¹⁰⁴, R¹¹⁰ and R¹¹¹ as defined herein.
k is an integer of from 0 to 8, e.g. 0, 1, 2, 3, 4, 5, 6, 7 or 8. Preferably k is an integer from 0 to 4, e.g. 0, 1, 2, 3 or 4. More preferably k is 0 or 1. Most preferably k is 0.

R¹¹⁰ and R¹¹¹ may at each occurrence independently be selected from the group consisting of H, F and —CF₃, and preferably are at each occurrence independently H or F, and most preferably are H.

Examples of suitable and preferred norbornene monomers, polymers and methods for their synthesis are provided herein and can also be found in U.S. Pat. Nos. 5,468,819, 6,538,087, US 2006/0020068 A1, US 2007/0066775 A1, US 2008/0194740 A1, WO 2012/028278 A1, U.S. Pat. No. 9,583,713, WO 2012/028279 A1 and U.S. Pat. No. 9,175,123. For example, exemplary polymerizations processes employing Group VIII transition metal catalysts are described in the aforementioned US 2006/0020068 A1.

The polymerization of the cycloolefin monomers, and particularly of the norbornene monomers, may be performed by irradiation or heat or both.

### Formulation

The present formulation comprises a transition metal compound as defined herein and one or more cycloolefin monomers, preferably norbornene monomers, as defined herein.

Said transition metal compound is selected from the group of platinum compound, palladium compound and ruthenium compound, with the palladium compound and the ruthenium compound being preferred.

The monomers comprised in the present formulation comprise at most 20 wt %, preferably at most 18 wt % or 16 wt %, more preferably at most 14 wt % or 12 wt %, even more preferably at most 10 wt % or 9.0 wt % or 8.0 wt % or 7.0 wt %, still even more preferably at most 6.0 wt %, and most preferably at most 5.0 wt % of atoms different from H, F and C (i.e. of “heteroatoms”), with wt % relative to the total weight of all monomers present in the formulation. Alternatively the monomers comprised in the present formulation may also comprise less than 5.0 wt %, for example at most 4.0 wt % or 3.0 wt % or 2.0 wt % or 1.0 wt % or 0.05 wt % or 0.01 wt %, with wt % relative to the total weight of the monomers present in the formulation, of atoms different from H, F and C.

The monomers comprised in the present formulation preferably comprise at least 50 wt % or 60 wt % or 70 wt %, more preferably at least 80 wt % or 90 wt %, even more preferably at least 95 wt % or 97 wt % or 99.0 wt %, still even more preferably at least 99.5 wt % or 99.7 wt % or 99.9 wt %, and most preferably consist of cycloolefin monomers as defined herein, with wt % being relative to the total weight of the monomers present in the formulation.

Preferably, the cycloolefin monomers comprised in the present formulation have a molecular weight of at most 1000 g mol⁻¹, more preferably of at most 900 g mol⁻¹ or 800 g mol⁻¹, even more preferably of at most 700 g mol⁻¹ or 600 g mol⁻¹, and most preferably of at most 500 g mol⁻¹.

Provided that the resulting formulation complies with above requirements regarding the content of H, F and C, the formulation may also comprise cycloolefin monomers, preferably norbornene monomers, comprising atoms other than H, F and C as defined above.

Optionally, the present formulation may further comprise at most 20 wt % (for example 18 wt %, 16 wt %, 14 wt % or 12 wt %), preferably at most 10 wt % (for example 9.0 wt %, 8.0 wt %, 7.0 wt %, 6.0 wt %, 5.0 wt %, 4.0 wt %, 3.0 wt % or 2.0 wt %), more preferably at most 1.0 wt % or 0.5 wt %, even more preferably at most 0.4 wt % or 0.3 w % or 0.2 wt % or 0.1 wt %, still even more preferably at most 0.05 wt % or 0.03 wt % or 0.01 wt %, with wt % relative to the total weight of monomers comprised in the formulation, and most preferably none, of cycloolefin monomers, preferably of norbornene monomers, comprising a reactive group as defined above.

It is noted that the present formulation may comprise more than one distinct type of monomer. Further monomers that may be comprised in the present formulation include, for example, hexene-1, hexene-2 and octene-1.

It is also noted that the definitions given above for the cycloolefin constitutional units and the norbornene constitutional units also apply to the respective cycloolefin monomers and norbornene monomers comprised in the present formulation.

In order to adapt the present formulation to the deposition method to be used the present formulation preferably comprises one or more viscosity modifier or binder.

Preferred binders according to the present invention are materials of low permittivity, that is, those having a permittivity E of 3.3 or less. The organic binder preferably has a permittivity E of 3.0 or less, more preferably 2.9 or less. Preferably the organic binder has a permittivity E of 1.7 or more. It is especially preferred that the permittivity of the binder is in the range from 2.0 to 2.9.

Preferred binders are polymers. Examples of such polymers may preferably selected from the group consisting of poly(α-methylstyrene), poly(4-methylstyrene), polystyrene, polystyrene-co-α-methylstyrene, polyvinylcinnamate, poly(4-vinylbiphenyl), poly(α-vinylnaphtalene), poly(vinyltoluene), polyethylene, cis-polybutadiene, polypropylene, polyisoprene, poly(4-methyl-1-pentene), poly (tetrafluoroethylene), poly(chorotrifluoroethylene), poly(2-methyl-1,3-butadiene), poly(p-xylylene), poly(α, α, α′, α′-tetrafluoro-p-xylylene), poly[1,1-(2-methyl propane)bis(4-phenyl)carbonate], poly(cyclohexyl methacrylate), poly(chlorostyrene), poly(2,6-dimethyl-1,4-phenylene ether), polyisobutylene, poly(vinyl cyclohexane), poly(ethylene/tetrafluoroethylene), poly(ethylene/chlorotrifluoroethylene), fluorinated ethylene/propylene copolymer, ethylene/ethyl acrylate copolymer, poly(styrene/10% butadiene), poly(styrene/15% butadiene), poly(styrene/2,4 dimethylstyrene), polycycloolefin as defined herein, and any blend of any of these. Preferably the binder is selected from the group consisting of poly(α-methylstyrene), poly(4-methylstyrene), polystyrene, polystyrene-co-α-methylstyrene, polycycloolefin as defined herein, and any blend of any of these. Most preferably the binder is selected from the group consisting of polystyrene, polycycloolefin as defined herein, and any blend of these.

The viscosity of the present formulations depends upon the method used to deposit the formulation and is therefore not particularly limited.

It is, however, preferred that for ink jet printing, nozzle printing and spin coating the formulation has a viscosity at 25° C. of at most 20 mPas, more preferably of at most 18 mPas or 16 mPas, even more preferably of at most 14 MPas or 12 mPas, and most preferably of at most 10 mPas. Preferably a formulation for ink jet printing and/or nozzle printing has a viscosity of at least 0.1 mPas or 0.5 mPas.

For other deposition methods, such as screen printing, gravure printing, doctor blade coating, roller printing, reverse-roller printing, offset lithography printing, dry offset lithography printing, flexographic printing, web printing, spray coating, curtain coating, brush coating, slot dye coating or pad printing, higher viscosities may be preferred. For such deposition processes the formulation preferably has a viscosity at 25° C. of at least 10 mPas, preferably of at least 100 mPas and most preferably of at least 1000 mPas, and of at most 5000 mPas.

As optional component, the present formulation may comprise an organic solvent. Said organic solvent is comprised in the formulation in preferably at most 1.0 wt % (for example 0.9 wt %, 0.8 wt %, 0.7 wt %, 0.6 wt %, 0.5 wt %, 0.4 wt %, 0.3 wt %, 0.2 wt %, or 0.1 wt %), with wt % relative to the total weight of said formulation.

Preferred examples of such solvents may be selected from the group consisting of aliphatic hydrocarbons, chlorinated hydrocarbons, aromatic hydrocarbons, ketones, ethers and mixtures thereof. More preferred examples are selected from the group consisting of alcohols, ethers, haloalkanes and any mixture of these.

Exemplary solvents which may be used include decane, dodecane, 1,2,4-trimethylbenzene, 1,2,3,4-tetra-methyl benzene, pentylbenzene, mesitylene, cumene, cymene, cyclohexylbenzene, diethylbenzene, tetralin, decalin, 2,6-lutidine, 2-fluoro-m-xylene, 3-fluoro-o-xylene, 2-chlorobenzotrifluoride, N,N-dimethylformamide, 2-chloro-6-fluorotoluene, 2-fluoroanisole, anisole, 2,3-dimethylpyrazine, 4-fluoroanisole, 3-fluoroanisole, 3-trifluoro-methylanisole, 2-methylanisole, phenetol, 4-methylanisole, 3-methylanisole, 4-fluoro-3-methylanisole, 2-fluorobenzonitrile, 4-fluoroveratrol, 2,6-dimethylanisole, 3-fluorobenzo-nitrile, 2,5-dimethylanisole, 2,4-dimethylanisole, benzonitrile, 3,5-dimethyl-anisole, N;N-dimethylaniline, ethyl benzoate, 1-fluoro-3,5-dimethoxy-benzene, 1-methylnaphthalene, N-methylpyrrolidinone, 3-fluorobenzo-trifluoride, benzotrifluoride, dioxane, trifluoromethoxy-benzene, 4-fluorobenzotrifluoride, 3-fluoropyridine, toluene, 2-fluoro-toluene, 2-fluorobenzotrifluoride, 3-fluorotoluene, 4-isopropylbiphenyl, phenyl ether, pyridine, 4-fluorotoluene, 2,5-difluorotoluene, 1-chloro-2,4-difluorobenzene, 2-fluoropyridine, 3-chlorofluoro-benzene, 1-chloro-2,5-difluorobenzene, 4-chlorofluorobenzene, chloro-benzene, o-dichlorobenzene, 2-chlorofluorobenzene, p-xylene, m-xylene, o-xylene or mixture of o-, m-, and p-isomers. Examples of especially preferred solvents include, without limitation, dichloromethane, trichloromethane, chlorobenzene, o-dichlorobenzene, tetrahydrofuran, anisole, morpholine, toluene, o-xylene, m-xylene, p-xylene, 1,4-dioxane, acetone, nnethylethylketone, 1,2-dichloroethane, 1,1,1-trichloroethane, 1,1;2,2-tetrachloroethane, ethyl acetate, n-butyl acetate, N,N-dimethylformamide, dimethylacetamide, dimethylsulfoxide, tetraline, decaline, indane, methyl benzoate, ethyl benzoate, mesitylene and/or mixtures thereof, preferably decane and dodecane.

Deposition

The present formulation is preferably deposited onto the base member by any method selected from the group consisting of dip coating, spin coating, ink jet printing, nozzle printing, letter-press printing, screen printing, gravure printing, doctor blade coating, roller printing, reverse-roller printing, offset lithography printing, dry offset lithography printing, flexographic printing, web printing, spray coating, curtain coating, brush coating, slot dye coating or pad printing. Of these, ink jet printing and nozzle jet printing are preferred.

Ink jet printing is particularly preferred when high resolution layers and devices need to be prepared. Selected formulations of the present invention may be applied to prefabricated device substrates by ink jet printing or microdispensing. Preferably industrial piezoelectric print heads such as but not limited to those supplied by Aprion, Hitachi-Koki, InkJet Technology, On Target Technology, Picojet, Spectra, Trident, Xaar may be used to apply the present formulation to a substrate. Additionally semi-industrial heads such as those manufactured by Brother, Epson, Konica, Seiko Instruments Toshiba TEC or single nozzle microdispensers such as those produced by Microdrop and Microfab may be used.

In case the formulation comprises a solvent, such solvent is preferably removed following the deposition of the formulation onto the base member. Such solvent removal may be done, for example, by heating the base member with the formulation deposited thereon to a temperature that is preferably above the boiling point of the solvent.

Device

In general terms the present application also relates to an electronic device, preferably an organic electronic device, comprising a base member, and a polycycloolefin layer, which may be produced in accordance with the present method as described herein.

Said base member is not particularly limited and may, in principle, be any member (for example, a substrate or a device or device component, all of which are described in the following) whereupon a polycycloolefin layer may be deposited. Without wishing to be bound by theory, this polycycloolefin layer is believed to contribute to protecting the underlying base member from water, oxygen, dust, or any other materials harmful to the underlying base member.

The base member is preferably an electronic device or a component of an electronic device, and more preferably an organic electronic device or a component of an organic electronic devices.

Examples of such base members may be selected from the group of electronic devices consisting of light emitting diodes, photovoltaic cells, photodetector cells, semiconductor devices, and thin film transistors, all of which may be organic, inorganic or hybrid.

Generally such electronic device comprises, preferably in sequence, a first electrode, a functional layer, and a second electrode. The functional layer may, for example, be selected from the group consisting of light emitting layer, semiconductor layer, and photoactive layer.

For the purposes of simplification the present application will use a light emitting diode as illustrative, non limiting example, but can easily be applied to any other device.

Such light emitting diode comprises, preferably in sequence, a first electrode (e.g. as anode), a light emitting layer, and a second electrode (e.g. as cathode). More preferably, the light emitting diode comprises, preferably in sequence, a first electrode (e.g. as anode), a hole transport layer, a light emitting layer, an electron transport layer, and the second electrode (e.g. as cathode).

Depending upon the architecture of the resulting electronic device, the polycycloolefin layer may be on the side of (but not necessarily directly adhered thereto) the first electrode or the second electrode.

Optionally, the present electronic device further comprises a layer, selected from the group consisting of organic layer, inorganic layer and hybrid layer, on top of (e.g. “adhered to” or “adjacent to”) the polycycloolefin layer. Said inorganic layer preferably comprises or consists of a material selected from the group consisting of silicon oxide, silicon nitride, silicon oxynitride, aluminum oxynitride, magnesium oxide, aluminum oxide, aluminum nitride, titanium oxide, titanium nitride, tantalum oxide, tantalum nitride, hafnium oxide, hafnium nitride, zirconium oxide, zirconium nitride, cerium oxide, cerium nitride, tin oxide, tin nitride and any blend of any of these. Most preferably said inorganic layer consists of silicon nitride.

Said one or more additional layers may also comprise the layers of a touch panel.

In a specific aspect, the present application relates to a display device comprising in sequence a substrate, a circuit layer, a display layer (comprising, preferably in sequence, a first electrode, electrode (e.g. as anode), a hole transport layer, a light emitting layer, an electron transport layer, and the second electrode (e.g. as cathode)), a planarization layer, a thin film encapsulation layer and a touch sensor layer.

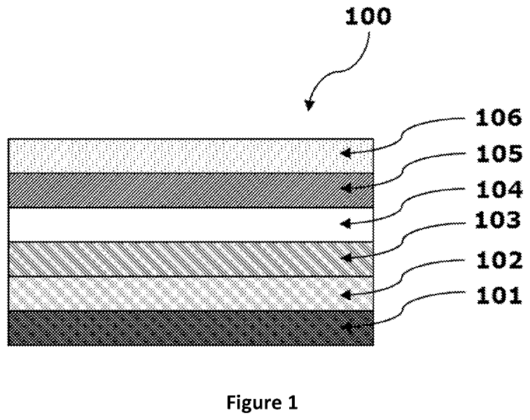

An exemplary schematic representation of such a display device comprising a touch panel is given in FIG. 1. Such display devices are well known to the skilled person and need therefore not be described in detail.

The substrate, whether as part of a base member or in itself constituting the base member, is not particularly limited. Suitable substrates are preferably inert under use conditions. Such substrates may, for example, be flexible. Preferred examples of suitable substrate materials may be selected from polymers, glass, metals and any blend of any of these, including for example blends of more than one polymer or metal. Preferred polymeric materials include but are not limited to alkyd resins, allyl esters, benzocyclobutenes, butadiene-styrene, cellulose, cellulose acetate, epoxide, epoxy polymers, ethylene-chlorotrifluoro ethylene copolymers, ethylene-tetra-fluoroethylene copolymers, fiber glass enhanced polymers, fluorocarbon polymers, hexafluoropropylenevinylidene-fluoride copolymer, high density polyethylene, parylene, polyamide, polyimide, polyaramid, polydimethylsiloxane, polyethersulphone, polyethylene, polyethylenenaphthalate, polyethyleneterephthalate, polyketone, polymethylmethacrylate, polypropylene, polystyrene, polysulphone, polytetrafluoroethylene, polyurethanes, polyvinylchloride, polycycloolefin, silicone rubbers, and silicones. Of these polyethyleneterephthalate, polyimide, polycycloolefin and polyethylenenaphthalate materials are more preferred. Additionally, for some embodiments of the present invention the substrate can be any suitable material, for example a polymeric material, metal or glass material coated with one or more of the above listed materials or coated with one or more metal, such as for example titanium. It will be understood that in forming such a substrate, methods such as extruding, stretching, rubbing or photochemical techniques can be employed to provide a homogeneous surface for device fabrication. Alternatively, the substrate can be a polymeric material, metal or glass coated with one or more of the above polymeric materials.

The circuit layer comprises one or more insulating layers, one or more conductive layers and at least one semiconductor layer. The conductive layers comprised in the circuit layer may form signal lines or a signal array of the pixel of the display.

The display layer comprises a plurality of light emitting diodes, which may either be organic or inorganic, but preferably are organic light emitting diodes.

The touch sensor layer comprises a plurality of touch sensors and a plurality of touch signal lines.

The thin film encapsulation layer comprises at least an inorganic layer. Such inorganic layer may, for example, comprise or consist of one selected from the group consisting of silicon oxide, silicon nitride, silicon oxynitride, aluminum oxynitride, magnesium oxide, aluminum oxide, aluminum nitride, titanium oxide, titanium nitride, tantalum oxide, tantalum nitride, hafnium oxide, hafnium nitride, zirconium oxide, zirconium nitride, cerium oxide, cerium nitride, tin oxide, tin nitride and any blend of any of these. Preferably such inorganic layer comprises or consists of silicon nitride, silicon oxynitride, silicon oxide, and any blend thereof. Most preferably, such inorganic layer consists of silicon nitride.

The thin film encapsulation layer preferably further comprises an organic layer. Such organic layer may, for example, consist of a polyacrylate or a polymethacrylate.

If said thin film encapsulation layer comprises an inorganic layer and an organic layer, it is preferably arranged in such a way that the inorganic layer is directly adjacent to the planarization layer.

1. Method for producing a film, said method comprising the steps of
(a) providing an base member;
(b) depositing the formulation as defined in any one or more of claims 25 to 37 on the base member; and
(c) polymerizing the monomers comprised in said formulation to obtain a polycycloolefin layer.

2. Method according to claim 1, wherein the base member is a electronic device, preferably a light emitting device.

3. Method according to claim 1, wherein in step (b) the formulation is deposited by a method selected from the group consisting of dip coating, spin coating, ink jet printing, nozzle printing, letter-press printing, screen printing, gravure printing, doctor blade coating, roller printing, reverse-roller printing, offset lithography printing, dry offset lithography printing, flexographic printing, web printing, spray coating, curtain coating, brush coating, slot dye coating or pad printing.

4. Method according to claim 1, wherein in step (b) the formulation is deposited by ink jet printing or nozzle printing.

5. Method according to claim 1, wherein step (c) is performed by irradiation or heat or both.

6. Method according to claim 1, further comprising the step of
(d) depositing one or more additional layers onto the polycycloolefin layer.

7. Method according to claim 6, wherein in step (d) the one or more additional layers are selected from the group consisting of organic layers, inorganic layers and hybrid layers.

8. Method according to claim 6, wherein the one or more additional layer is an inorganic layer comprising a material selected from the group consisting of silicon oxide, silicon nitride, silicon oxynitride, aluminum oxynitride, magnesium oxide, aluminum oxide, aluminum nitride, titanium oxide, titanium nitride, tantalum oxide, tantalum nitride, hafnium oxide, hafnium nitride, zirconium oxide, zirconium nitride, cerium oxide, cerium nitride, tin oxide, tin nitride and any blend of any of these; preferably silicon nitride.

9. Method according to claim 6, wherein in step (d) the one or more additional layers comprise the layers of a touch panel.

10. (canceled)

11. (canceled)

12. (canceled)

13. (canceled)

14. (canceled)

15. Polycycloolefin comprising at most 20 wt % of atoms different from H, F and C, with wt % being relative to the total weight of the polycycloolefin.

16. Polycycloolefin according to claim 15 having a permittivity E of at most 4.0, determined at 20° C. and 1,000 Hz.

17. Polycycloolefin according to claim 15 comprising at least 50 wt % of cycloolefin constitutional units, with wt % being relative to the total weight of the polycycloolefin.

18. Polycycloolefin according to claim 15 having a weight average molecular weight of at least 100,000 g mol⁻¹, determined by GPC.

19. Polycycloolefin according to claim 15, wherein the polycycloolefin is a polynorbornene.

20. Polycycloolefin according to claim 15, wherein the cycloolefin constitutional units are norbornene constitutional units of the following formula (II′) or formula (II″) 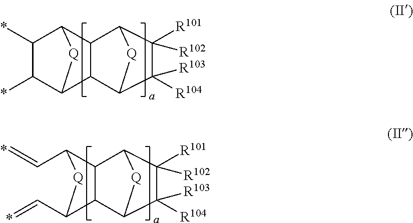
wherein
a is at each occurrence independently an integer of from 0 to 5;
Q is at each occurrence independently selected from the group consisting of —CH₂—, —CH₂—CH₂—, —CF₂—, —CF₂—CF₂— and O;
R¹⁰¹, R¹⁰², R¹⁰³, and R¹⁰⁴ are at each occurrence independently of each other selected from the group consisting of hydrogen, fluorine, hydrocarbyl groups, partially fluorinated hydrocarbyl groups and fully fluorinated hydrocarbyl groups.

21. Polycycloolefin according to claim 15, wherein the polycycloolefin is a polynorbornene comprising norbornene constitutional units derived from the respective monomers, which are at each occurrence independently selected from the group consisting of the following formulae formula (II-a-01) to (II-a-19) 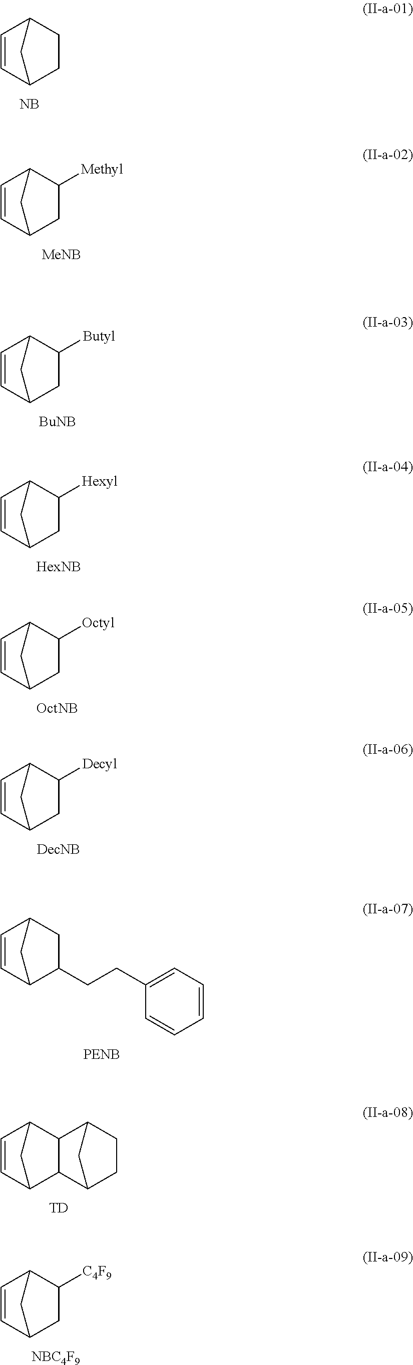 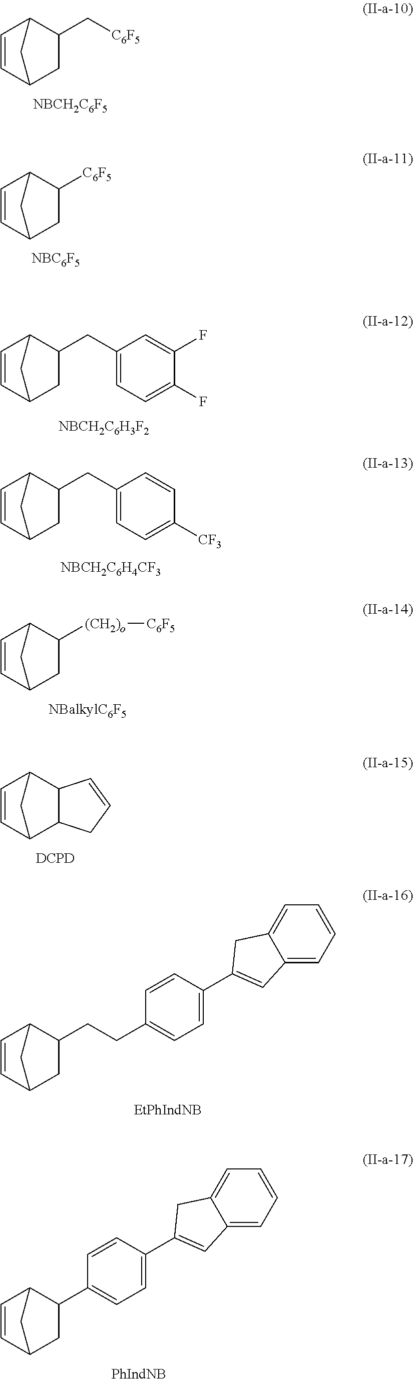 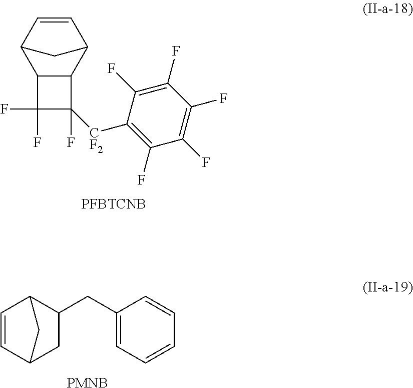
wherein “Me” stands for methyl, “Et” for ethyl, “Ph” and “C₆H₅” for phenyl, “C₆F₅” for pentafluorophenyl, o is an integer from 1 to 8; and for each of the above subformulae having a methylene bridging group (a CH₂ covalently bonded to both the norbornene ring and a functional group), including but not limited to (II-a-10), (II-a-12), (II-a-13) and (II-a-19), it will be understood that the methylene bridging group can be replaced by a covalent bond or —(CH₂)ₒ— as in formula (II-a-14), with o then being an integer from 1 to 6.

22. Polycycloolefin according to claim 15, further comprising cycloolefin constitutional units comprising a reactive group, with wt % relative to the total weight of the polycycloolefin.

23. Polycycloolefin according to claim 22, wherein the cycloolefin constitutional units comprise a reactive group that is at each occurrence independently selected from the group consisting of alkylidene groups (—(R¹⁰⁸)C═C(R¹⁰⁸)—), alkynyl groups (—C≡C—), maleimide; maleimide substituted with one or more groups R¹⁰⁸, preferably alkyl having from 1 to 10, more preferably from 1 to 5 carbon atoms, and most preferably with methyl or ethyl; maleimide having one or more (for example, 1, 2 or 3) annealed aromatic, preferably 6-membered, rings such that the 3- and 4-positions of the maleimide form part of one of the aromatic rings; epoxide, vinyl, acetylene, indenyl, cinnamate, coumarin, dicyclopentadiene and derivatives thereof, for example those wherein one or more hydrogen atoms are replaced by R¹⁰⁸;
with R¹⁰⁸ being at each occurrence independently selected from the group consisting of halogen, preferably fluorine; alkyl having from 1 to 10, preferably from 1 to 5 carbon atoms, more preferably methyl; partially or fully halogenated, preferably fluorinated, alkyl having from 1 to 10, preferably from 1 to 5 carbon atoms, more preferably methyl; alkoxy having from 1 to 10, preferably from 1 to 5 carbon atoms, more preferably methoxy; and partially or fully halogenated, preferably fluorinated, alkoxy having from 1 to 10, preferably from 1 to 5 carbon atoms, more preferably methoxy.

24. Polycycloolefin according to claim 22, wherein the cycloolefin constitutional units comprising a reactive group are norbornene constitutional units that are at each occurrence independently selected from the group consisting of the following formulae (II-c-01) to (II-c-27) 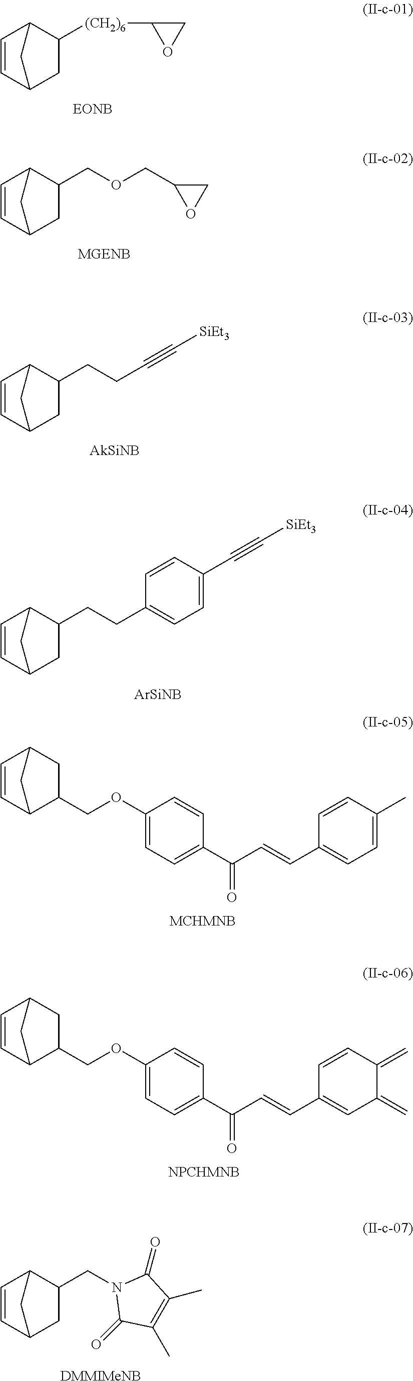 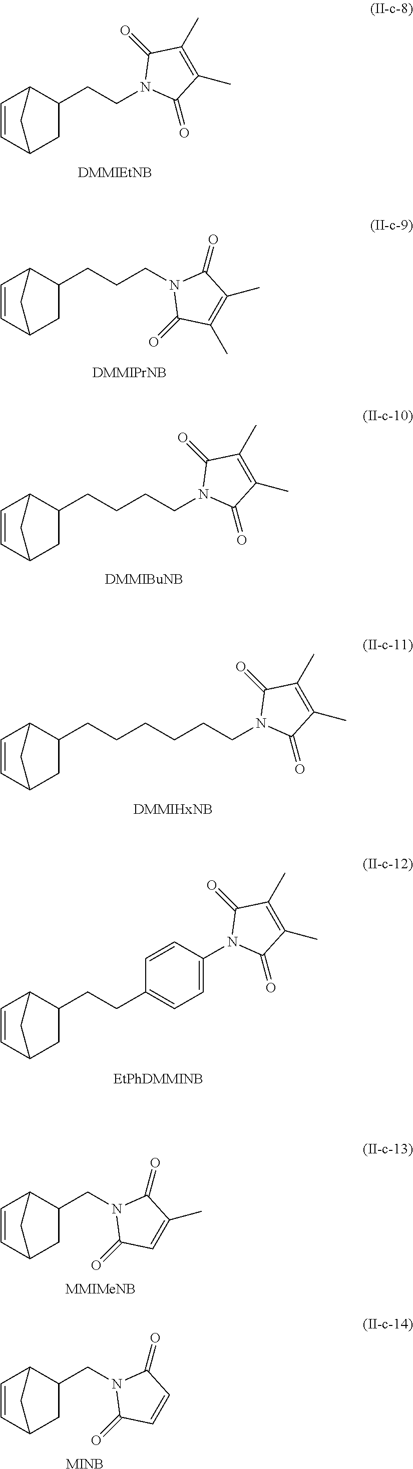 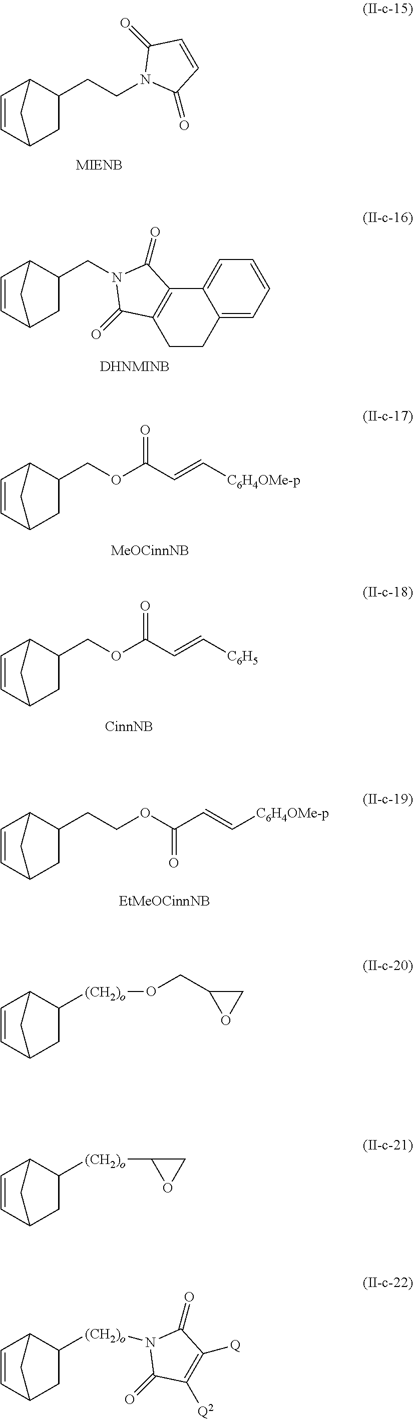 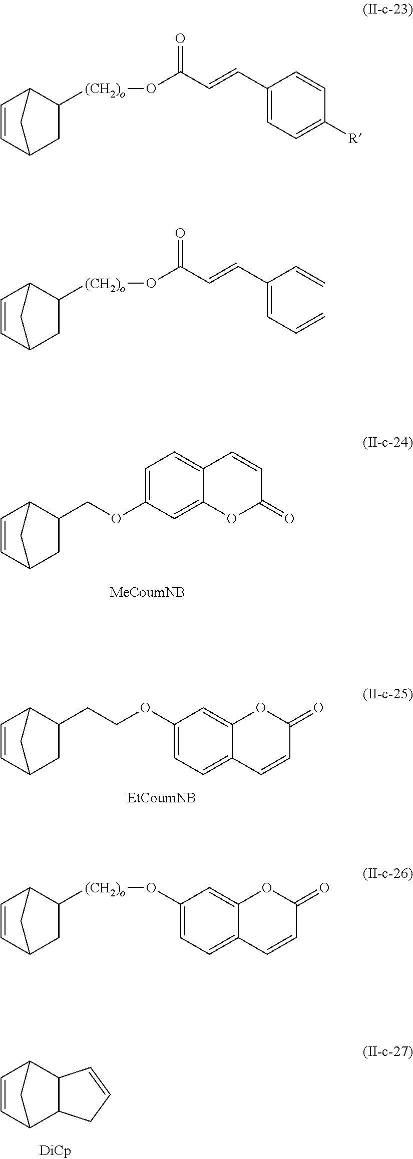
wherein “Me” stands for methyl, “Et” for ethyl, “OMe-p” for para-methoxy, “Ph” and “C₆H₅” for phenyl, “C₆H₄” for phenylene, “C₆F₅” for pentafluorophenyl, “OAc” for acetate, “PFAc” for —OC(O)—C₇F₁₅, o is an integer from 1 to 8, Q1 and Q2 are at each occurrence independently H or —CH₃; R′ is H or —OCH₃; and for each of the above subformulae having a methylene bridging group (a CH₂ covalently bonded to both the norbornene ring and a functional group), including but not limited to (II-c-02), (II-c-05), (II-c-06), (II-c-07), (II-c-13), (II-c-14), (II-c-16), (II-c-17), (II-c-18), and (II-c-24), it will be understood that the methylene bridging group can be replaced by a covalent bond or —(CH₂)ₒ— as, for example, in formula (II-c-20), with o then being an integer from 1 to 6.

25. Formulation comprising a transition metal compound and one or more cycloolefin monomers, wherein said cycloolefin monomers comprise at most 5 wt % of atoms different from H, F and C, with wt % relative to the total weight of the cycloolefin monomers.

26. Formulation according to claim 25 comprising at least 50 wt % of cycloolefin monomers, with wt % being relative to the total weight of the formulation.

27. Formulation according to claim 25, wherein the cycloolefin monomers are norbornene monomers.

28. Formulation according to claim 25, wherein the cycloolefin monomers are norbornene monomers of the formula (II′) 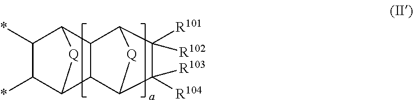
wherein
a is at each occurrence independently an integer of from 0 to 5;
Q is at each occurrence independently selected from the group consisting of —CH₂—, —CH₂—CH₂—, —CF₂—, —CF₂—CF₂— and O;
R¹⁰¹, R¹⁰², R¹⁰³, and R¹⁰⁴ are at each occurrence independently of each other selected from the group consisting of hydrogen, fluorine, hydrocarbyl groups, partially fluorinated hydrocarbyl groups and fully fluorinated hydrocarbyl groups.

29. Formulation according to claim 25, wherein the cycloolefin monomers are norbornene monomers, which are at each occurrence independently selected from the group consisting of the formulae (II-a-1) to (II-a-19) 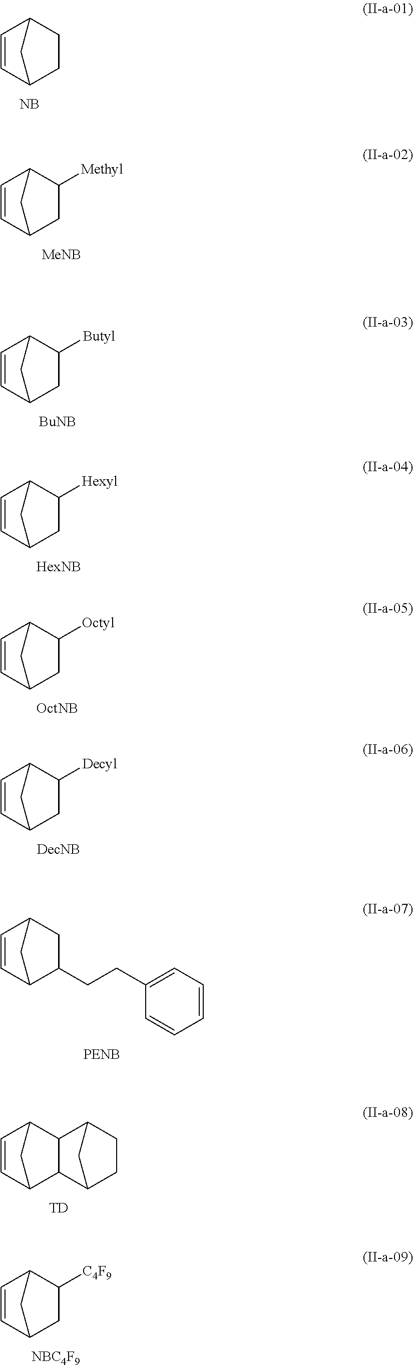 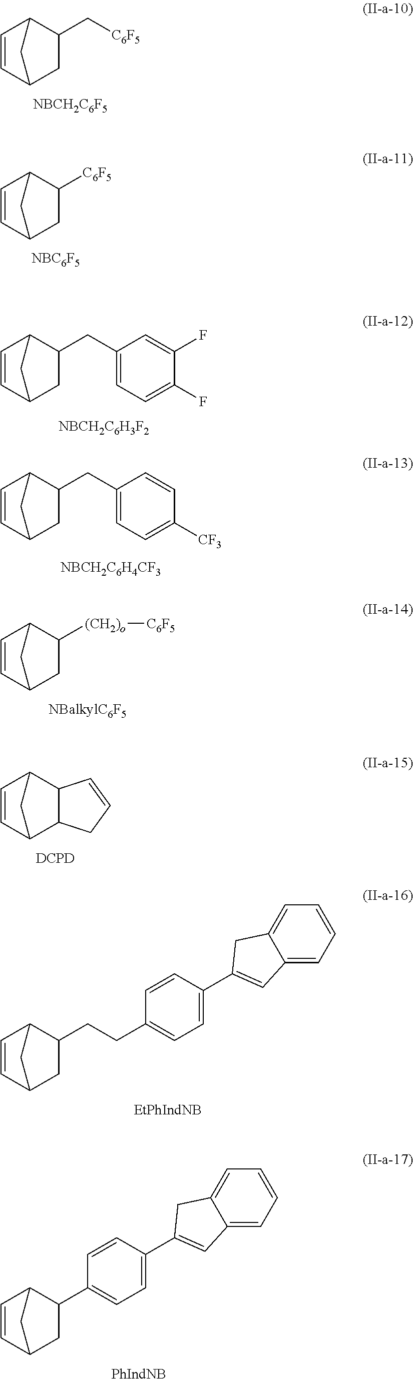 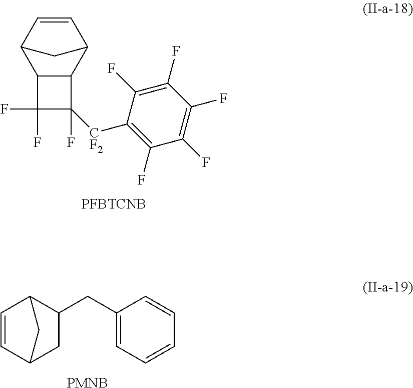
wherein “Me” stands for methyl, “Et” for ethyl, “Ph” and “C₆H₅” for phenyl, “C₆F₅” for pentafluorophenyl, o is an integer from 1 to 8; and for each of the above subformulae having a methylene bridging group (a CH₂ covalently bonded to both the norbornene ring and a functional group), including but not limited to (II-a-10), (II-a-12), (II-a-13) and (II-a-19), it will be understood that the methylene bridging group can be replaced by a covalent bond or —(CH₂)ₒ— as in formula (II-a-14), with o then being an integer from 1 to 6.

30. Formulation according to claim 25, further comprising at most 1.0 wt % of cycloolefin monomers comprising a reactive group, with wt % relative to the total weight of the cycloolefin monomers.

31. Formulation according to claim 30, wherein the cycloolefin monomers comprise a reactive group that is at each occurrence independently selected from the group consisting of alkylidene group (—(R¹⁰⁸)C═C(R¹⁰⁸)—), alkynyl groups (—C≡C—), maleimide; maleimide substituted with one or more groups R¹⁰⁸, preferably alkyl having from 1 to 10, more preferably from 1 to 5 carbon atoms, and most preferably with methyl or ethyl; maleimide having one or more (for example, 1, 2 or 3) annealed aromatic, preferably 6-membered, rings such that the 3- and 4-positions of the maleimide form part of one of the aromatic rings; epoxide, vinyl, acetylene, indenyl, cinnamate, coumarin, dicyclopentadiene and derivatives thereof, for example those wherein one or more hydrogen atoms are replaced by R¹⁰⁸;
with R¹⁰⁸ being at each occurrence independently selected from the group consisting of halogen, preferably fluorine; alkyl having from 1 to 10, preferably from 1 to 5 carbon atoms, more preferably methyl; partially or fully halogenated, preferably fluorinated, alkyl having from 1 to 10, preferably from 1 to 50 carbon atoms, more preferably methyl; alkoxy having from 1 to 10, preferably from 1 to 5 carbon atoms, more preferably methoxy; and partially or fully halogenated, preferably fluorinated, alkoxy having from 1 to 10, preferably from 1 to 5 carbon atoms, more preferably methoxy.

32. Formulation according to claim 30, wherein the cycloolefin monomers are norbornene monomers that are at each occurrence independently selected from the group consisting of the formulae (II-c-01) to (II-c-27) 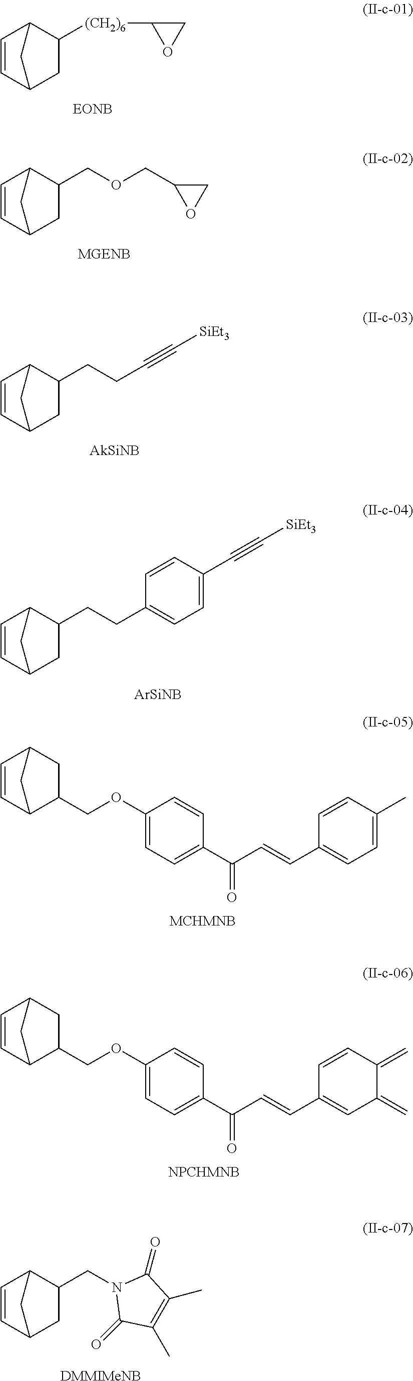 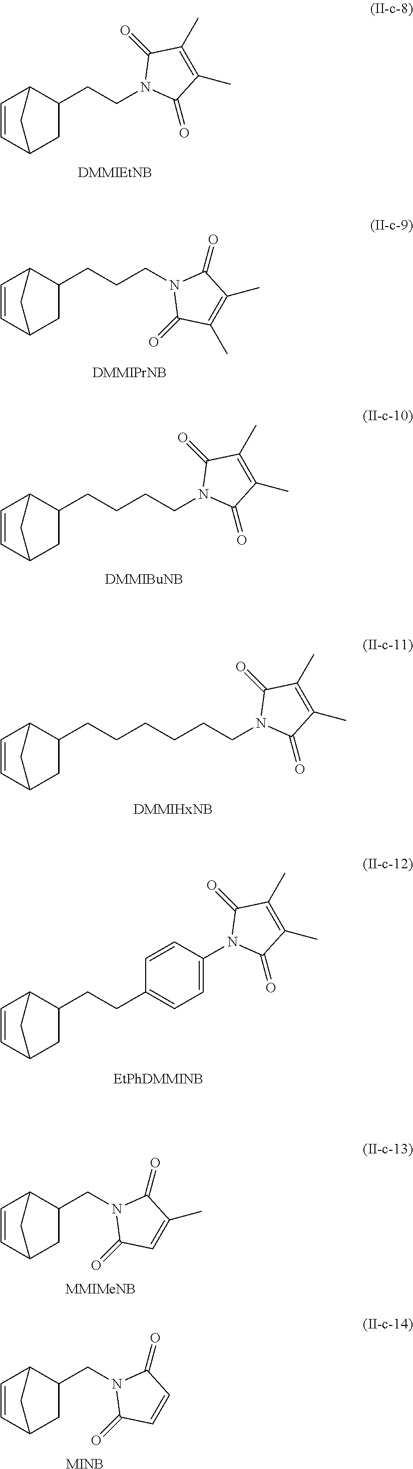 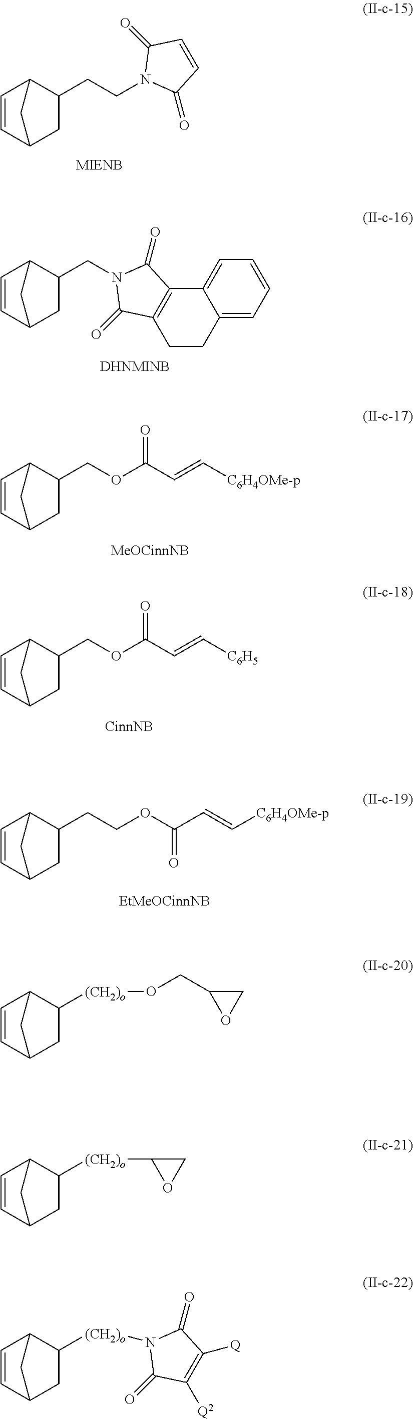 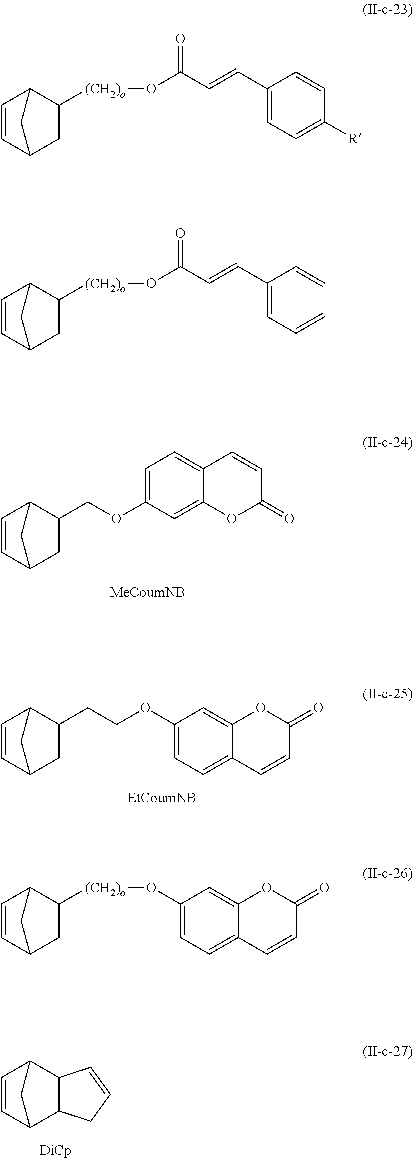
wherein “Me” stands for methyl, “Et” for ethyl, “OMe-p” for para-methoxy, “Ph” and “C₆H₅” for phenyl, “C₆H₄” for phenylene, “C₆F₅” for pentafluorophenyl, “OAc” for acetate, “PFAc” for —OC(O)—C₇F₁₅, o is an integer from 1 to 8, Q1 and Q2 are at each occurrence independently H or —CH₃; R′ is H or —OCH₃; and for each of the above subformulae having a methylene bridging group (a CH₂ covalently bonded to both the norbornene ring and a functional group), including but not limited to (II-c-02), (II-c-05), (II-c-06), (II-c-07), (II-c-13), (II-c-14), (II-c-16), (II-c-17), (II-c-18), and (II-c-24), it will be understood that the methylene bridging group can be replaced by a covalent bond or —(CH₂)ₒ— as, for example, in formula (II-c-20), with o then being an integer from 1 to 6.

33. Formulation according to claim 25, which is an ink having a viscosity at 25° C. of at most 20 mPas.

34. Formulation according to claim 25 further comprising a binder, preferably a polymeric binder, and most preferably polystyrene.

35. Formulation according to claim 25, wherein the transition metal compound is selected from the group of platinum compound, palladium compound and ruthenium compound.

36. Formulation according to claim 25, wherein the transition metal is comprised in an amount of at most 1.0 wt % (for example 0.9, 0.8, 0.7, 0.6, 0.5, 0.4, 0.3, 0.2, 0.1 or 0.05), with wt % relative to the total weight of cycloolefin monomers.

37. Formulation according to claim 25, wherein the formulation comprises at most 10.0 wt % (for example 9.0, 8.0, 7.0, 6.0, 5.0, 4.0, 3.0, 2.5, 2.0, 1.5, 1.0 or 0.5 wt %) of solvent, with wt % relative to the total weight of the formulation.

38. Electronic device comprising
(a) a base member; and
(b) a polycycloolefin film (layer) comprising the polycycloolefin of claim 15.

39. Electronic device according to claim 38, wherein the base member is an electronic device, preferably an light emitting device.

40. Electronic device according to claim 38, wherein the base member is a light emitting device comprising in sequence a first electrode (anode), a light emitting layer, and a second electrode (cathode).

41. Electronic device according to claim 38, wherein the base member is an organic light emitting device comprising in sequence a first electrode (anode), a hole transport layer, a light emitting layer, an electron transport layer, and the second electrode (cathode).

42. Electronic device according to claim 38, further comprising an inorganic layer inorganic layer comprising a material selected from the group consisting of: silicon oxide, silicon nitride, silicon oxynitride, aluminum oxynitride, magnesium oxide, aluminum oxide, aluminum nitride, titanium oxide, titanium nitride, tantalum oxide, tantalum nitride, hafnium oxide, hafnium nitride, zirconium oxide, zirconium nitride, cerium oxide, cerium nitride, tin oxide, tin nitride and any blend of any of these; on top of the second electrode.
